(19) United States
(12) Patent Application Publication
(10) Pub. No.: US 2026/0309659 A1
(43) Pub. Date: Oct. 8, 2026

(54) APPARATUS AND METHOD FOR MEASURING ELECTROCHEMICAL IMPEDANCE SPECTROSCOPY

(71) Applicant: SK On Co., Ltd., Seoul (KR)

(72) Inventors: Kyu Min HWANG, Daejeon (KR); Jae Hee LEE, Daejeon (KR); Hyun Jun LEE, Daejeon (KR); Ung JON, Daejeon (KR)

(21) Appl. No.: 19/640,444

(22) Filed: Apr. 7, 2026

(30) Foreign Application Priority Data
Apr. 7, 2025 (KR) 10-2025-0044984

(51) Int. Cl. G01N 27/02; G01R 31/389; G01R 31/392; G01R 31/396; H01M 10/42

(52) U.S. Cl. CPC G01N 27/026; G01N 27/028; G01R 31/389; G01R 31/392; G01R 31/396; H01M 10/425; H01M 2010/4271

(57) ABSTRACT

Proposed are an apparatus and a method for measuring electrochemical impedance spectroscopy (EIS) of a battery. The apparatus includes an EIS measurement unit connected to each of a plurality of battery cells included in a battery module and configured to perform electrochemical impedance spectroscopy (EIS) measurement on each of the plurality of battery cells through AC discharge of the battery module, and an AC discharge switching unit connected to both ends of the battery module and configured to form an AC discharge path such that the battery module performs AC discharge through a pulse width modulation (PWM) control of a switching element when the EIS measurement unit performs electrochemical impedance spectroscopy (EIS) measurement or configured to be used as an additional function through a turn-on control of the switching element when the EIS measurement unit does not perform electrochemical impedance spectroscopy (EIS) measurement.

### CROSS REFERENCE TO RELATED APPLICATION

The present application claims priority to Korean Patent Application No. 10-2025-0044984, filed on Apr. 7, 2025, the entire contents of which are incorporated herein for all purposes by this reference.

### TECHNICAL FIELD

The present disclosure relates to an apparatus and a method for measuring electrochemical impedance spectroscopy (EIS) of a battery.

### BACKGROUND

An electric vehicle (EV) refers to a vehicle that is driven using electrical energy and is equipped with a battery configured to supply electric power. The battery serves as a power source for driving an electric motor for driving the vehicle.

The electric vehicle is connected to a charger for charging the battery, and the battery is charged by electric power supplied from the charger to the electric vehicle.

Such an electric vehicle is further equipped with a battery management system (BMS) configured to diagnose and control charging and discharging states of the battery in order to improve efficiency of the battery and maximize service life thereof.

Meanwhile, for diagnosing a state of a battery, impedance measurement based on electrochemical impedance spectroscopy (EIS) has recently been utilized and extensive research has been conducted on methods capable of diagnosing even defects of the battery using electrochemical impedance spectroscopy.

### SUMMARY

According to one aspect of the present disclosure, there are provided an apparatus and a method for measuring electrochemical impedance spectroscopy, which are capable of performing electrochemical impedance spectroscopy (EIS) measurement on a battery.

According to one aspect of the present disclosure, there are provided an apparatus and a method for measuring electrochemical impedance spectroscopy, which are capable of improving accuracy during electrochemical impedance spectroscopy (EIS) measurement of a battery.

An apparatus and a method for measuring electrochemical impedance spectroscopy according to one aspect of the present disclosure are widely applied to green technologies such as electric vehicles, battery charging stations, and other methods such as photovoltaic power generation and wind power generation using batteries.

An apparatus and a method for measuring electrochemical impedance spectroscopy according to one aspect of the present disclosure are applied to eco-friendly electric vehicles, hybrid vehicles, and the like for preventing climate change by suppressing air pollution and greenhouse gas emissions.

An apparatus for measuring electrochemical impedance spectroscopy according to one aspect of the present disclosure includes an EIS measurement unit connected to each of a plurality of battery cells included in a battery module and configured to perform electrochemical impedance spectroscopy (EIS) measurement on each of the plurality of battery cells through AC discharge of the battery module, and an AC discharge switching unit connected to both ends of the battery module and configured to form an AC discharge path such that the battery module performs AC discharge through a pulse width modulation (PWM) control of a switching element when the EIS measurement unit performs electrochemical impedance spectroscopy (EIS) measurement and configured to be used as an additional function through a turn-on control of the switching element when the EIS measurement unit does not perform electrochemical impedance spectroscopy (EIS) measurement.

According to an exemplary embodiment, the AC discharge switching unit may be used for heating the battery module when the EIS measurement unit does not perform electrochemical impedance spectroscopy (EIS) measurement.

According to an exemplary embodiment, the AC discharge switching unit may include a multifunction switching unit electrically connected to the battery module including the plurality of battery cells and configured to comprise the switching element for generating an alternating current, a switching control unit configured to control the switching element by pulse width modulation (PWM) according to a predetermined frequency when electrochemical impedance spectroscopy (EIS) measurement is performed, and to control the switching element in an on/off manner when electrochemical impedance spectroscopy (EIS) measurement is not performed, a multipurpose function unit connected between the battery module and the multifunction switching unit and configured to form the AC discharge path when the switching element is controlled by pulse width modulation (PWM), or to function for heating the battery module when the switching element is turned on, and a sensing resistor unit connected between the battery module including the plurality of battery cells and the multifunction switching unit.

According to an exemplary embodiment, the EIS measurement unit, the multifunction switching unit, and the switching control unit may be included in a battery management system (BMS) for managing a state of the battery module, and the multipurpose function unit may include a heating element to be mounted on a vehicle.

According to an exemplary embodiment, the multipurpose function unit may include a heater resistor to be mounted on the battery module for heating the battery module.

According to an exemplary embodiment, the multipurpose function unit may have one end of the heater resistor connected to a positive terminal of the battery module and have the other end thereof connected to the switching element of the multifunction switching unit, and may form the AC discharge path of the battery module through the heater resistor by allowing the switching control unit to control the switching element of the multifunction switching unit by pulse width modulation (PWM) during electrochemical impedance spectroscopy (EIS) measurement.

According to an exemplary embodiment, one end of the heater resistor connected to a positive terminal of the battery module and the other end of the heater resistor is connected to the switching element of the multifunction switching unit, and may use the heater resistor for heating the battery module by allowing the switching control unit to turn on the switching element of the multifunction switching unit when electrochemical impedance spectroscopy (EIS) measurement is not performed.

According to an exemplary embodiment, the AC discharge switching unit may further include a fault diagnosis switch having one end thereof connected between the multipurpose function unit and the multifunction switching unit and the other end connected to a negative terminal of the battery module so as to diagnose a fault of the multifunction switching unit.

According to an exemplary embodiment, when the switching control unit controls the switching element of the multifunction switching unit by pulse width modulation (PWM) according to a predetermined AC frequency such that AC discharge is performed in the battery module through the multipurpose function unit, the EIS measurement unit may operate to receive a value obtained by measuring an AC discharge current formed on the switching element using the sensing resistor unit by the switching control unit, to measure an AC discharge voltage reacting to each of the plurality of battery cells included in the battery module, and to calculate an impedance for each of the plurality of battery cells using the measured AC discharge current and the measured discharge voltage.

According to an exemplary embodiment, protective fuses for protecting electrochemical impedance spectroscopy (EIS) measurement paths may be connected between the EIS measurement unit and respective nodes of a plurality of battery cells included in the battery module.

A method for measuring electrochemical impedance spectroscopy according to one aspect of the present disclosure includes generating an alternating current corresponding to a frequency for electrochemical impedance spectroscopy (EIS) measurement of a battery module by an AC discharge switching unit connected to the battery module including a plurality of battery cells, and performing electrochemical impedance spectroscopy (EIS) measurement on each of the plurality of battery cells included in the battery module by an EIS measurement unit connected to respective nodes of the plurality of battery cells included in the battery module, wherein the AC generation step includes controlling, by a switching control unit of the AC discharge switching unit, a switching element of a multifunction switching unit in a pulse width modulation (PWM) manner, and forming an AC discharge path passing through a multipurpose function unit by repetitive on/off operation of the switching element under a pulse width modulation (PWM) control, such that the battery module performs AC discharge.

According to an exemplary embodiment, the EIS measurement step may include receiving, by the EIS measurement unit, an AC discharge current measurement value from the switching control unit that measures an AC discharge current formed on the switching element using a sensing resistor unit, measuring, by the EIS measurement unit, an AC discharge voltage that reacts to each of the plurality of battery cells included in the battery module, and calculating, by the EIS measurement unit, an impedance for each of the plurality of battery cells using the measured AC discharge current and the measured AC discharge voltage.

According to an exemplary embodiment, the method may further comprise an additional function step of operating a multipurpose function unit as an additional function by turning on a switching element of a multifunction switching unit under control of a switching control unit of an AC discharge switching unit when electrochemical impedance spectroscopy (EIS) measurement is not performed.

According to an exemplary embodiment, the additional function step may use the multipurpose function unit for heating a battery module.

According to an exemplary embodiment, the method may further include diagnosing whether the switching element of the multifunction switching unit is faulty, wherein the fault diagnosis step uses a fault diagnosis switch having one end connected between the multipurpose function unit and the multifunction switching unit and the other end connected to a negative terminal of the battery module.

The features and advantages of the present disclosure will become more apparent from the following detailed description with reference to the accompanying drawings.

The terms and words used in the present specification and the claims should not be construed as having ordinary or dictionary meanings, but should be interpreted as meanings and concepts consistent with the technical spirit of the present disclosure, on the basis of the principle that the inventor may appropriately define the concepts of terms in order to describe his or her invention in the best way.

According to an exemplary embodiment of the present disclosure, it is possible to perform electrochemical impedance spectroscopy (EIS) measurement of a battery.

According to an exemplary embodiment of the present disclosure, it is possible to set an AC discharge current for electrochemical impedance spectroscopy (EIS) measurement of a battery to a large value.

According to an exemplary embodiment of the present disclosure, it is possible to improve accuracy when electrochemical impedance spectroscopy (EIS) measurement of a battery is performed.

According to an exemplary embodiment of the present disclosure, it is possible to perform an additional function in addition to a main function of measuring electrochemical impedance spectroscopy (EIS) of a battery.

According to an exemplary embodiment of the present disclosure, it is possible to use an apparatus for heating a battery when electrochemical impedance spectroscopy (EIS) measurement of a battery is not performed.

According to an exemplary embodiment of the present disclosure, it is possible to diagnose whether an apparatus is faulty.

### BRIEF DESCRIPTION OF THE DRAWINGS

FIG. 1 is a view illustrating an apparatus for measuring electrochemical impedance spectroscopy according to an exemplary embodiment.

FIG. 2 is a view illustrating a configuration of an AC discharge switching unit in an apparatus for measuring electrochemical impedance spectroscopy according to an exemplary embodiment.

FIG. 3 is a view illustrating a detailed configuration of an AC discharge switching unit in an apparatus for measuring electrochemical impedance spectroscopy according to an exemplary embodiment.

FIG. 4 is a view illustrating a heater resistor forming a multipurpose function unit in an apparatus for measuring electrochemical impedance spectroscopy according to an exemplary embodiment.

FIG. 5 is a view illustrating an impedance measurement principle of an EIS measurement unit in an apparatus for measuring electrochemical impedance spectroscopy according to an exemplary embodiment.

FIG. 6 is a view illustrating a fault diagnosis switch in an apparatus for measuring electrochemical impedance spectroscopy according to an exemplary embodiment.

FIG. 7 is a view illustrating a method for measuring electrochemical impedance spectroscopy according to an exemplary embodiment.

FIG. 8 is a view illustrating an AC generation step in a method for measuring electrochemical impedance spectroscopy according to an exemplary embodiment.

FIG. 9 is a view illustrating an EIS measurement step in a method for measuring electrochemical impedance spectroscopy according to an exemplary embodiment.

### DETAILED DESCRIPTION

Hereinafter, the present disclosure will be described in detail (with reference to the accompanying drawings). However, this may be only illustrative, and the present disclosure is not limited to the specific exemplary embodiments described as examples.

The drawings may be displayed schematically or in an exaggerated manner for the purpose of explaining the exemplary embodiments.

In this document, expressions such as "include," "may include," "have," "may have," and the like may indicate the presence of a corresponding feature (e.g., numerical values, functions, operations, or parts as components) and may not preclude the presence of additional features.

Hereinafter, an exemplary embodiment of the present disclosure will be described in detail with reference to the accompanying drawings.

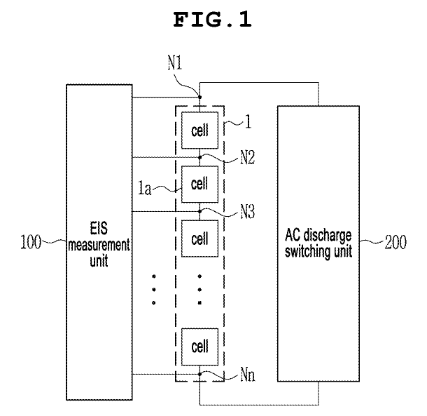

FIG. 1 is a view illustrating an apparatus for measuring electrochemical impedance spectroscopy according to an exemplary embodiment.

Referring to FIG. 1, an apparatus for measuring electrochemical impedance spectroscopy according to an exemplary embodiment may include an EIS measurement unit 100 connected to each of a plurality of battery cells 1a included in a battery module 1 and configured to perform electrochemical impedance spectroscopy (EIS) measurement on each of the plurality of battery cells 1a through AC discharge of the battery module 1, and an AC discharge switching unit 200 connected to both ends of the battery module 1 and configured to form an AC discharge path such that the battery module 1 performs AC discharge through pulse width modulation (PWM) control of a switching element when the EIS measurement unit 100 performs electrochemical impedance spectroscopy (EIS) measurement or configured to be used as an additional function through turn-on control of the switching element when the EIS measurement unit 100 does not perform electrochemical impedance spectroscopy (EIS) measurement.

The battery module 1 may have a plurality of battery cells 1a electrically connected. The battery module 1 may have the plurality of battery cells 1a connected in series or connected in parallel, or may be in a form of a combination of series and parallel.

The EIS measurement unit 100 may be connected to the battery module 1 and perform electrochemical impedance spectroscopy (EIS) measurement for diagnosing a state of the battery module 1. The EIS measurement unit 100 may be electrically connected to each of the plurality of battery cells 1a. The EIS measurement unit 100 may be connected to each node (N1–Nn) of the plurality of battery cells 1a included in the battery module 1 and perform electrochemical impedance spectroscopy (EIS) measurement for each battery cell 1a. Each node (N1 to Nn) of the plurality of battery cells 1a may be a connection line for connecting the battery cells 1a to each other. Each node (N1 to Nn) of the plurality of battery cells 1a may correspond to each of the plurality of battery cells 1a included in the battery module 1, and may serve as a voltage measurement node for measuring a voltage of the corresponding battery cell by the EIS measurement unit 100.

Electrochemical impedance spectroscopy (EIS) may be a technique for diagnosing a battery by measuring an impedance, which corresponds to a total component generated when an alternating current or voltage is applied. Electrochemical impedance spectroscopy (EIS) may diagnose the manufacturing defects, internal short circuits, overcharge or overdischarge, and remaining capacity of the battery. Electrochemical impedance spectroscopy (EIS) may reduce inspection time and cost as compared with conventional battery inspection methods.

The AC discharge switching unit 200 may perform AC discharge in units of the battery module 1 such that the EIS measurement unit 100 performs impedance measurement by electrochemical impedance spectroscopy (EIS) for each of the plurality of battery cells 1a included in the battery module 1. In this case, the alternating current applied through the AC discharge may be a perturbation current that induces discharge from the battery module 1.

The AC discharge switching unit 200 may be electrically connected to the battery module 1 including a plurality of battery cells 1a and may form an AC discharge path such that a discharge current having an alternating current component flows by repetitive on/off operation of the switching element according to pulse width modulation (PWM) control. The AC discharge switching unit 200 may cause the battery module 1 to perform AC discharge through the pulse width modulation (PWM) method. Accordingly, the EIS measurement unit 100 may perform electrochemical impedance spectroscopy (EIS) measurement on each of the plurality of battery cells 1a on the basis of the AC discharge of the battery module 1.

The AC discharge switching unit 200 may be used for an additional function by controlling a switching element to be turned on when the EIS measurement unit 100 does not perform electrochemical impedance spectroscopy (EIS) measurement. The AC discharge switching unit 200 may be used to operate as a resistive load by controlling the switching element to be turned on when the EIS measurement unit 100 does not perform electrochemical impedance spectroscopy (EIS) measurement. For example, it may be used for heating the battery module 1 to a predetermined temperature. The AC discharge switching unit 200 may be electrically connected to the battery module 1 including the plurality of battery cells 1a and may be used for heating the battery module 1 by controlling in an on/off switching manner. The AC discharge switching unit 200 may operate as a power consumption path for heating the battery module 1 when the switching element is controlled to be turned on.

Accordingly, in the present disclosure, the AC discharge switching unit 200 may cause the battery module 1 to perform AC discharge through switching control of the switching element, and the EIS measurement unit 100 may perform electrochemical impedance spectroscopy (EIS) measurement. In addition, the AC discharge switching unit 200 may perform a function as a resistive load for heating the battery module 1 through switching control of the switching element.

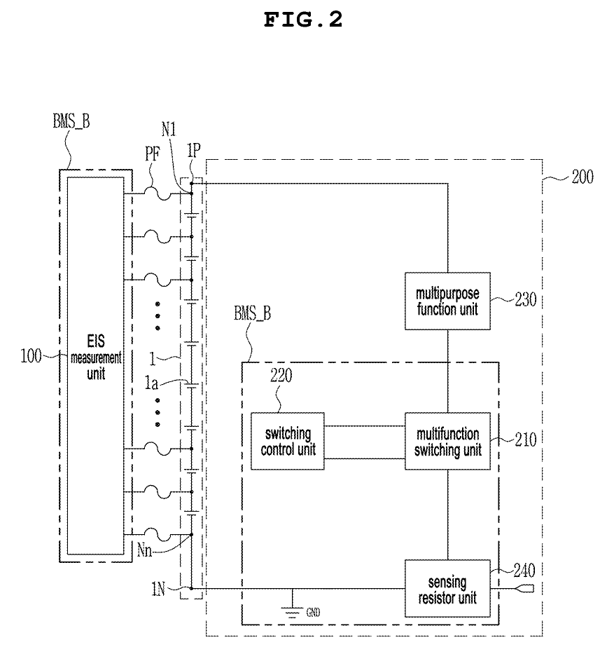

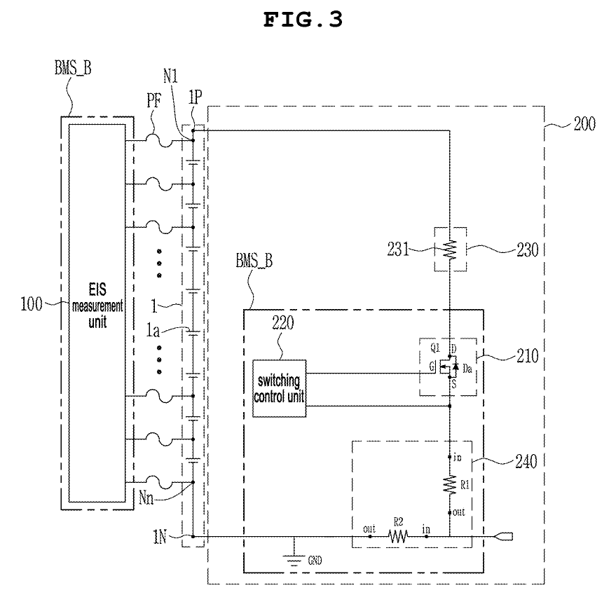

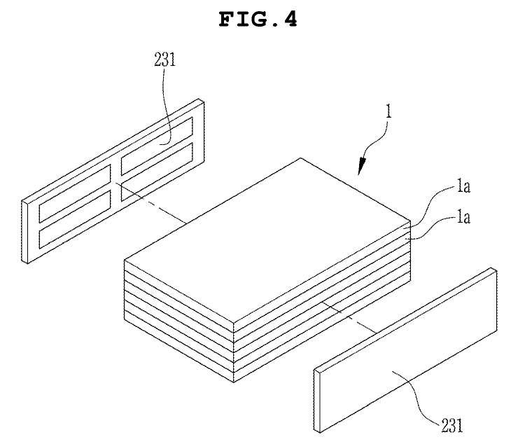

FIG. 2 is a view illustrating a configuration of an AC discharge switching unit in an apparatus for measuring electrochemical impedance spectroscopy according to an exemplary embodiment, FIG. 3 is a view illustrating a detailed configuration of an AC discharge switching unit in an apparatus for measuring electrochemical impedance spectroscopy according to an exemplary embodiment, and FIG. 4 is a view illustrating a heater resistor forming a multipurpose function unit in an apparatus for measuring electrochemical impedance spectroscopy according to an exemplary embodiment.

Referring to FIGS. 2 and 3, in the present disclosure, the EIS measurement unit 100 may have a measurement path protection fuse (PF) for protecting an electrochemical impedance spectroscopy (EIS) measurement path connected to each connection to respective nodes (N1–Nn) of the plurality of battery cells 1a included in the battery module 1. The flow of overcurrent may be blocked.

The EIS measurement unit 100 may perform electrochemical impedance spectroscopy (EIS) measurement in response to AC discharge of the battery module 1.

Referring to FIGS. 2 to 4, in the present disclosure, the AC discharge switching unit may include a multifunction switching unit 210 electrically connected to the battery module 1 including the plurality of battery cells 1a and configured to include a switching element (Q1) for generating an alternating current, a switching control unit 220 configured to control the switching element (Q1) by pulse width modulation (PWM) according to a predetermined frequency when electrochemical impedance spectroscopy (EIS) measurement is performed, and to control the switching element (Q1) in an on/off manner when electrochemical impedance spectroscopy (EIS) measurement is not performed, a multipurpose function unit 230 connected between the battery module 1 and the multifunction switching unit 210 and configured to form an AC discharge path when the switching element (Q1) is controlled by pulse width modulation (PWM), or to function for heating the battery module 1 when the switching element (Q1) is turned on, and a sensing resistor unit 240 connected between the battery module 1 including the plurality of battery cells 1a and the multifunction switching unit 210.

The multifunction switching unit 210 may perform a switching operation by pulse width modulation (PWM) control so as to generate an alternating current corresponding to a predetermined frequency for electrochemical impedance spectroscopy (EIS) measurement. The multifunction switching unit 210 may perform a switching operation by an on/off control when electrochemical impedance spectroscopy (EIS) measurement is not performed. That is, the multifunction switching unit 210 may perform a dual-function switching operation for transmitting signals different from each other.

The multifunction switching unit 210 may include a switching element (Q1), and the switching element (Q1) may be a field effect transistor (FET). A source terminal (S) of the switching element (Q1) may be connected in series to a negative terminal (1N) of the battery module 1, a drain terminal (D) may be connected to the multipurpose function unit 230, and the gate terminal (G) may be connected to the switching control unit 220.

The multifunction switching unit 210 may further include a diode (Da) connected to the switching element (Q1). An anode of the diode (Da) may be connected to the source terminal (S) of the switching element (Q1), and a cathode may be connected to the drain terminal (D) of the switching element (Q1).

The switching control unit 220 may control the operation of the multifunction switching unit 210. The switching control unit 220 may control the switching element (Q1) of the multifunction switching unit 210 to repeatedly switch on and off through pulse width modulation (PWM) control so as to generate an alternating current when the EIS measurement unit 100 performs electrochemical impedance spectroscopy (EIS) measurement. When electrochemical impedance spectroscopy (EIS) measurement is not performed in the EIS measurement unit 100, the switching control unit 220 may control the switching element (Q1) of the multifunction switching unit 210 to be turned on or off.

The multipurpose function unit 230 may perform the function of stably forming an AC discharge path in the battery module 1. It achieves this by having durability to withstand power consumption generated during AC discharge. An alternating current is generated by controlling the switching element (Q1) of the multifunction switching unit 210 using pulse width modulation (PWM). In addition, the multipurpose function unit 230 may perform an additional function when the switching element (Q1) of the multifunction switching unit 210 is turned on. The multipurpose function unit 230 may perform a function of maintaining a predetermined temperature by heating the battery module 1. That is, the multipurpose function unit 230 may form an AC discharge path or operate as a resistive load for heating the battery module 1 depending on the control method of the switching element (Q1). The multipurpose function unit 230 may be referred to as a ″resistive load unit″.

In the present disclosure, the EIS measurement unit 100, the multifunction switching unit 210, and the switching control unit 220 may be included in the battery management system (BMS) that manages the state of the battery module 1, and the multipurpose function unit 230 may include a heating element to be mounted on a vehicle or ESS(Energy Storage System) structure. The EIS measurement unit 100, the multifunction switching unit 210, and the switching control unit 220 may be mounted on a BMS board (BMS_B) for the battery management system (BMS). The multipurpose function unit 230 may be a component individually positioned outside the BMS board (BMS_B). The switching control unit 220 may be implemented as a single EIS chip together with the EIS measurement unit 100.

As illustrated in FIG. 4, the multipurpose function unit 230 may include a heater resistor 231 to be mounted in the battery module 1 for heating the battery module 1. The heater resistor 231 may be assembled to the battery module 1. The heater resistor 231 may have various shapes. For example, the heater resistor 231 may have a planar shape. However, the present disclosure is not limited to this example.

Referring to FIG. 3, the multipurpose function unit 230 may have one end of the heater resistor 231 connected to the positive terminal (1P) of the battery module 1, and have the other end connected to the switching element (Q1) of the multifunction switching unit 210, the switching control unit 220 may control the switching element (Q1) of the multifunction switching unit 210 by pulse width modulation (PWM) during electrochemical impedance spectroscopy (EIS) measurement, and an AC discharge path of the battery module 1 may be formed through the heater resistor 231. The multipurpose function unit 230 may allow the switching control unit 220 to control the switching element (Q1) in the pulse width modulation (PWM) manner during electrochemical impedance spectroscopy (EIS) measurement and may form the AC discharge path so that a discharge current having an AC component can flow through the heater resistor 231.

The multipurpose function unit 230 may set the magnitude of the AC discharge current to be large when forming the AC discharge path of the battery module 1 so as to perform electrochemical impedance spectroscopy (EIS) measurement by utilizing the heater resistor 231 individually positioned on the outside of the BMS board (BMS_B). In a conventional configuration in which a resistor or other elements are mounted on the BMS board (BMS_B) to form an AC discharge path, there has been a limitation in that a magnitude of the AC discharge current should be reduced to less than 1 A in order to ensure stable operation. In addition, in the prior art, a rest period may have been required at the time of measurement in consideration of heat generation during use. In the present disclosure, it is possible to stably handle an AC discharge current in the range of at least 1 A to at most 10 A by utilizing the heater resistor 231. In the present disclosure, it is possible to continuously perform electrochemical impedance spectroscopy (EIS) measurement without the rest period by minimizing heat generation during use. In the present disclosure, it is possible to eliminate elements such as resistors conventionally mounted on the BMS board (BMS_B) to form the AC discharge path and it is possible to reduce the size of the BMS board (BMS_B). In the present disclosure, it is possible to improve accuracy during electrochemical impedance spectroscopy (EIS) measurement because the magnitude of the AC discharge current can be set to be large through the heater resistor 231.

Referring to FIG. 3, the multipurpose function unit 230 may have one end of the heater resistor 231 connected to the positive terminal (1P) of the battery module 1 and have the other end connected to the switching element (Q1) of the multifunction switching unit 210, and may use the heater resistor 231 for heating the battery module 1 by allowing the switching control unit 220 to turn on the switching element (Q1) of the multifunction switching unit 210 when electrochemical impedance spectroscopy (EIS) measurement is not performed. When electrochemical impedance spectroscopy (EIS) measurement is not performed, the multipurpose function unit 230 may operate the heater resistor 231 as a heating load for heating the battery module 1 by controlling the switching control unit 220 to turn on the switching element (Q1).

The multipurpose function unit 230 may perform a function of maintaining a predetermined temperature by heating the battery module 1 by operating the heater resistor 231 when the switching element (Q1) of the multifunction switching unit 210 is turned on by utilizing the heater resistor 231 mounted on the battery module 1. The heater resistor 231 may function to heat the battery module 1 in an environment below 0°C, for example, and to maintain an appropriate temperature at which the battery module 1 can operate.

Referring to FIG. 3, the sensing resistor unit 240 may include at least one resistance element for detecting, in a voltage form, an AC discharge current flowing for electrochemical impedance spectroscopy (EIS) measurement. For example, the sensing resistor unit 240 may have two resistance elements (R1, R2) connected in series. The first resistor (R1) of the sensing resistor unit 240 may have one end (in) connected in series to the switching element (Q1) of the multifunction switching unit 210 and have the other end (out) connected to one end (in) of the second resistor (R2). The second resistor (R2) of the sensing resistor unit 240 may have the other end (out) connected to a negative terminal (1N) of the battery module 1 and to the ground (GND).

When forming an AC discharge path through the multipurpose functional unit 230, the switching control unit 220 may measure the voltage applied to the sensing resistor unit 240 and control the switching element (Q1) of the multifunction switching unit 210 by pulse width modulation (PWM) so as to maintain a predetermined AC frequency for electrochemical impedance spectroscopy (EIS) measurement.

The sensing resistor unit 240 may also be used to measure an AC discharge current formed on the switching element (Q1) during electrochemical impedance spectroscopy (EIS) measurement in the EIS measurement unit 100. The sensing resistor unit 240 may detect an AC discharge current flowing through the switching element (Q1).

Accordingly, in the present disclosure, by utilizing the heater resistor 231 mounted on the battery module 1 as the multipurpose function unit 230, it is possible to improve measurement accuracy during electrochemical impedance spectroscopy (EIS) measurement and to enable continuous measurement without the rest period. In addition, it is possible to simplify an apparatus such as eliminating elements mounted on the BMS board (BMS_B), and to reduce manufacturing costs. In the present disclosure, it is possible to control the switching element (Q1) of the multifunction switching unit 210 by pulse width modulation (PWM) through voltage measurement using the sensing resistor unit 240. Through this, it is possible to maintain a predetermined AC frequency for electrochemical impedance spectroscopy (EIS) measurement, and to more stably form an AC discharge path through the multipurpose function unit 230.

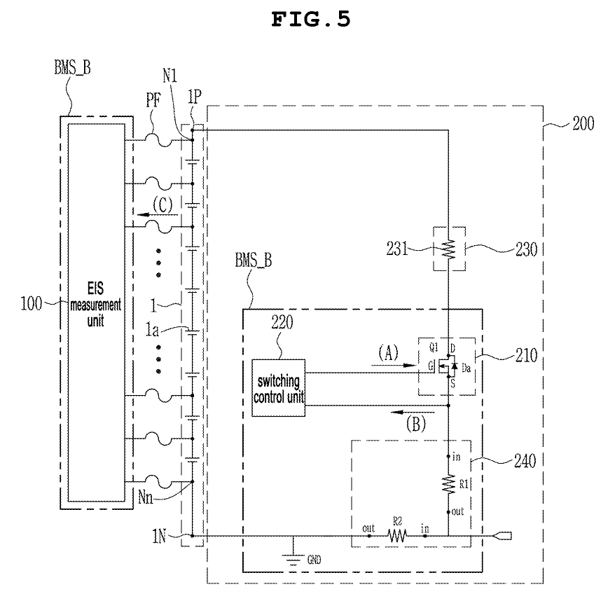

FIG. 5 is a view illustrating an impedance measurement principle of an EIS measurement unit in an apparatus for measuring electrochemical impedance spectroscopy according to an exemplary embodiment.

Referring to FIG. 5, in the apparatus for measuring electrochemical impedance spectroscopy according to the present disclosure, the EIS measurement unit 100 may [see FIG. 5B] receive a value obtained by measuring the AC discharge current formed on the switching element (Q1) by the switching control unit 220 using the sensing resistor unit 240 when AC discharge is performed in the battery module 1 through the multipurpose function unit 230 by [see FIG. 5A] controlling, by the switching control unit 220, the switching element (Q1) of the multifunction switching unit 210 by pulse width modulation (PWM) according to a predetermined AC frequency, and may [see FIG. 5C] measure the AC discharge voltage that reacts to each of the plurality of battery cells 1a included in the battery module 1, thereby calculating an impedance for each of the plurality of battery cells using the measured AC discharge current and the measured AC discharge voltage.

Referring to FIG. 5A, the switching control unit 220 may generate an alternating current by controlling the switching element (Q1) of the multifunction switching unit 210 by pulse width modulation (PWM) according to a predetermined AC frequency. The AC discharge path passing through the heater resistor 231 of the multipurpose function unit 230 may be formed by repeated switching operation of the switching element (Q1), such that AC discharge is performed in the battery module 1. When the battery module 1 performs AC discharge in this manner, the EIS measurement unit 100 may perform electrochemical impedance spectroscopy (EIS) measurement.

Referring to FIG. 5B, the EIS measurement unit 100 may receive a value obtained by measuring the AC discharge current formed on the switching element (Q1) by the switching control unit 220 using the sensing resistor unit 240.

When the battery module 1 performs AC discharge, a current flow may be formed in which the AC discharge current starts from the positive terminal (1P) of the battery module 1, passes through the multipurpose function unit 230 and the multifunction switching unit 210, and then flows to the negative terminal (1N) of the battery module 1 via the sensing resistor unit 240.

The switching control unit 220 may measure the voltage from the AC discharge current passing through the switching element (Q1) of the multifunction switching unit 210 by using the two resistance elements (R1, R2) connected in series in the sensing resistor unit 240. By dividing the measured voltage by the resistance value of the two series-connected resistance elements (R1, R2), it is possible to measure the AC discharge current formed on the switching element (Q1).

Referring to FIG. 5C, the EIS measurement unit 100 may measure each AC discharge voltage that reacts to each of the plurality of battery cells 1a included in the battery module 1 as the battery module 1 performs AC discharge.

Accordingly, the EIS measurement unit 100 of the present disclosure may measure an impedance for each of the plurality of battery cells 1a by calculating the value obtained by measuring the AC discharge voltage that reacts to each of the plurality of battery cells 1a and the value obtained by measuring the AC discharge current formed on the switching element (Q1) that is transmitted from the switching control unit 220.

In this manner, through the impedance measured for each of the plurality of battery cells 1a, it is possible to identify a current state of the battery module 1 as well as a current state of each of the plurality of battery cells 1a and to determine whether a defect is present.

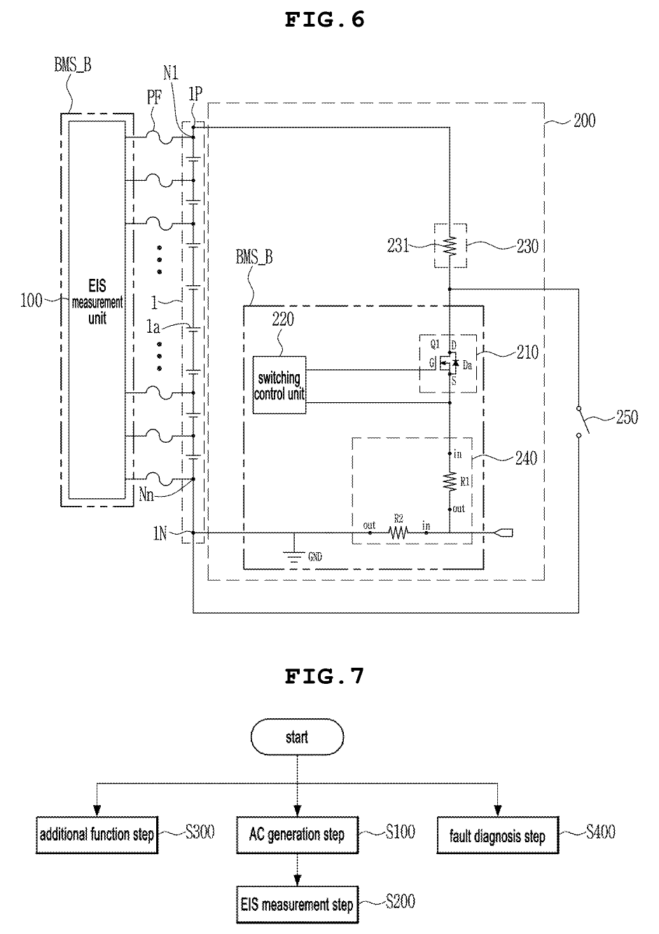

FIG. 6 is a view illustrating a fault diagnosis switch in an apparatus for measuring electrochemical impedance spectroscopy according to an exemplary embodiment.

Referring to FIG. 6, in the apparatus for measuring electrochemical impedance spectroscopy according to the present disclosure, the AC discharge switching unit 200 may further include a fault diagnosis switch 250 having one end thereof connected between the multipurpose function unit 230 and the multifunction switching unit 210 and the other end connected to the negative terminal (1N) of the battery module 1, for diagnosing a failure(or fault) of the multifunction switching unit 210.

The fault diagnosis switch 250 may be connected in parallel with the switching element (Q1). A relay may be used as the fault diagnosis switch 250. A contactless switch may also be used as the fault diagnosis switch 250. Examples of the contactless switch may include a silicon controller rectifier (SCR), an insulated gate bi-polar transistor (IGBT), and the like.

The fault diagnosis for the switching element (Q1) of the multifunction switching unit 210 using the fault diagnosis switch 250 will be described as follows.

When the current is measured in the switching element (Q1) of the multifunction switching unit 210 when the fault diagnosis switch 250 is switched on, the switching element (Q1) may be diagnosed as faulty because current should not flow to the switching element (Q1).

In addition, when the fault diagnosis switch 250 is switched off and the switching element (Q1) of the multifunction switching unit 210 is switched on, the switching element (Q1) may be diagnosed as faulty when no current is measured in the switching element (Q1) of the multifunction switching unit 210 or a current less than a predetermined threshold is measured.

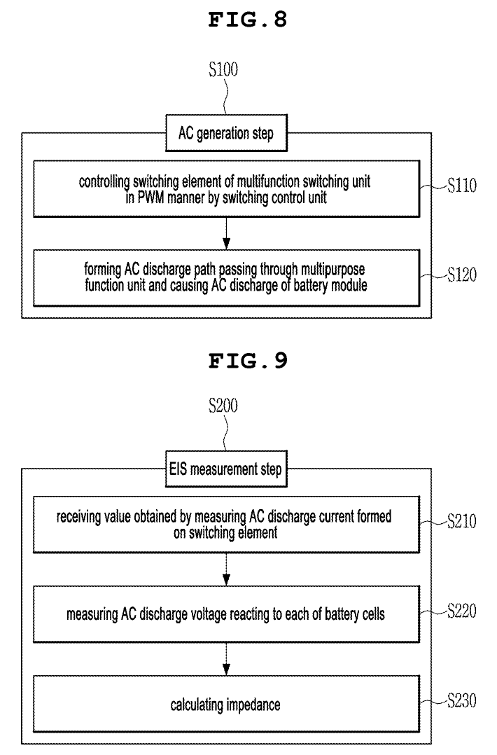

FIG. 7 is a view illustrating a method for measuring electrochemical impedance spectroscopy according to an exemplary embodiment, FIG. 8 is a view illustrating an AC generation step in a method for measuring electrochemical impedance spectroscopy according to an exemplary embodiment, and FIG. 9 is a view illustrating an EIS measurement step in a method for measuring electrochemical impedance spectroscopy according to an exemplary embodiment. FIGS. 1 to 6 are referred to together.

Referring to FIGS. 7 to 9, a method for measuring electrochemical impedance spectroscopy according to the present disclosure may include (S100) generating an alternating current corresponding to a frequency for electrochemical impedance spectroscopy (EIS) measurement of the battery module 1 by an AC discharge switching unit 200 connected to the battery module 1 including a plurality of battery cells 1a, and (S200) performing electrochemical impedance spectroscopy (EIS) measurement on each of the plurality of battery cells 1a included in the battery module 1 by an EIS measurement unit 100 connected to respective nodes (N1–Nn) of the plurality of battery cells 1a included in the battery module 1, wherein the AC generation step (S100) includes (S110) controlling a switching element (Q1) of a multifunction switching unit 210 using pulse width modulation (PWM) by a switching control unit 220 of the AC discharge switching unit 200, and (S120) forming an AC discharge path passing through a multipurpose function unit 230 by the repetitive on/off operation of the switching element (Q1) by pulse width modulation (PWM) control, such that the battery module 1 performs AC discharge.

The battery module 1 may have the plurality of battery cells 1a electrically connected. The battery module 1 may have the plurality of battery cells 1a connected in series or in parallel, or may be in a form connected in a combination of series and parallel.

In the AC generation step (S100), the AC discharge switching unit 200 may control the switching operation of the switching element (Q1) in a pulse width modulation (PWM) manner. By controlling the switching element (Q1) by pulse width modulation (PWM), an alternating current may be generated in the AC discharge switching unit 200 and an AC discharge path passing through the multipurpose function unit 230 may be formed. Accordingly, the battery module 1 may perform AC discharge through the electrically connected AC discharge switching unit 200. Such AC discharge may provide an environment in which electrochemical impedance spectroscopy (EIS) measurement can be performed in the EIS measurement unit 100.

The multipurpose function unit 230 may be mounted on the battery module 1, and disposed outside the BMS board (BMS_B) to be electrically connected. The multipurpose function unit 230 may be capable of setting the magnitude of the AC discharge current to be large.

In the EIS measurement step (S200), the EIS measurement unit 100 may measure each impedance on the basis of the reaction formed for each of the plurality of battery cells 1a in the battery module 1 in which AC discharge is performed. Through this, the current state of each battery cell 1a may be identified, and whether a defect is present may be determined.

As illustrated in FIG. 9, the EIS measurement step (S200) may include (S210) receiving, by the EIS measurement unit 100, an AC discharge current measurement value from the switching control unit 220 that measures the AC discharge current flowing through the switching element (Q1) using the sensing resistor unit 240, (S220) measuring, by the EIS measurement unit 100, the AC discharge voltage that reacts to each of the plurality of battery cells 1a included in the battery module 1, and (S230) calculating, by the EIS measurement unit 100, the impedance for each of the plurality of battery cells 1a using the measured AC discharge current and the measured AC discharge voltage.

The switching control unit 220 may measure the voltage from the AC discharge current passing through the switching element (Q1) of the multifunction switching unit 210 by using two resistance elements (R1, R2) connected in series and included in the sensing resistor unit 240. The AC discharge current formed on the switching element (Q1) may be measured by dividing the measured voltage by the resistance value of two series-connected resistance elements (R1, R2). The switching control unit 220 may transmit the AC discharge current measurement value to the EIS measurement unit 100.

As the AC discharge is performed in the battery module 1, the EIS measurement unit 100 may individually measure the AC discharge voltage generated corresponding to each of the plurality of battery cells 1a included in the battery module 1.

The EIS measurement unit 100 may calculate an impedance for each of the plurality of battery cells 1a by dividing an AC discharge voltage measurement value measured in the EIS measurement unit 100 by an AC discharge current measurement value received from the switching control unit 220.

Accordingly, in the present disclosure, it is possible to generate an alternating current and form an AC discharge path through the multipurpose function unit 230 by repeatedly switching the switching element (Q1) of the multifunction switching unit 210 under pulse width modulation (PWM) control. By forming an AC discharge path in the AC discharge switching unit 200, it is possible to perform electrochemical impedance spectroscopy (EIS) measurement on each of the plurality of battery cells 1a included in the battery module 1 in the EIS measurement unit 100. Accordingly, it is possible to identify the state of the battery module 1 and determine whether there is a defect in any of the plurality of battery cells 1a.

In addition, in the present disclosure, a magnitude of the AC discharge current may be set to a relatively large value through the multipurpose function unit 230. Accordingly, by allowing a relatively large AC discharge current to flow through the multipurpose function unit 230, it is possible to improve the reliability of the measurement signal and to increase the measurement efficiency. That is, it is possible to improve accuracy when the EIS measurement unit 100 performs electrochemical impedance spectroscopy (EIS) measurement on the battery module 1.

Referring to FIG. 7, the method for measuring electrochemical impedance spectroscopy according to the present disclosure may further include additional function step (S300) of operating the multipurpose function unit 230 for an additional function by turning on the switching element (Q1) of the multifunction switching unit 210 by the switching control unit 220 of the AC discharge switching unit 200 when the EIS measurement unit 100 does not perform electrochemical impedance spectroscopy (EIS) measurement.

The additional function step (S300) may be a step for performing additional functions in the apparatus in addition to a main function of performing electrochemical impedance spectroscopy (EIS) measurement.

The additional function step (S300) may use the multipurpose function unit 230 for heating the battery module 1. To this end, the multipurpose function unit 230 may include a heater resistor 231. The heater resistor 231 may be mounted on the battery module 1 and may be positioned outside the BMS board (BMS_B) to be electrically connected thereto. The heater resistor 231 may allow the magnitude of the AC discharge current to be set up to 10 A.

At this time, as illustrated in FIG. 4, the heater resistor 231 of the multipurpose function unit 230 may be mounted on the battery module 1 for heating the battery module 1, and as illustrated in FIG. 3, one end thereof may be connected to the positive terminal (1P) of the battery module 1, and the other end may be connected to the switching element (Q1) of the multifunction switching unit 210.

Accordingly, in the present disclosure, the multipurpose function unit 230 may be used to perform an additional function of the apparatus. That is, in the present disclosure, the heater resistor 231 may be used for various purposes, such as performing additional functions of the apparatus in addition to its main function of forming an AC discharge path for electrochemical impedance spectroscopy (EIS) measurement. In particular, by configuring the multipurpose function unit 230 with the heater resistor 231, it may be used for the purpose of heating the battery module 1 and maintaining a predetermined temperature.

In addition, referring to FIG. 7, the method for measuring electrochemical impedance spectroscopy according to the present disclosure may further include (S400) diagnosing whether the switching element (Q1) of the multifunction switching unit 210 is faulty, and the fault diagnosis step (S400) may use a fault diagnosis switch 250 having one end connected between the multipurpose function unit 230 and the multifunction switching unit 210 and the other end connected to the negative terminal (1N) of the battery module 1, as illustrated in FIG. 6.

In the fault diagnosis step S400, when current is measured in the switching element (Q1) of the multifunction switching unit 210 when the fault diagnosis switch 250 is switched on, the switching element (Q1) may be diagnosed as faulty.

In addition, in the fault diagnosis step (S400), when the fault diagnosis switch 250 is switched off and the switching element (Q1) of the multifunction switching unit 210 is switched on, the switching element (Q1) may be diagnosed as faulty when no current is measured in the switching element (Q1) of the multifunction switching unit 210 or when a current less than a predetermined threshold is measured.

As described above, through the present disclosure including the specific examples described above, it is possible to stably perform AC discharge of the battery module 1 and easily perform electrochemical impedance spectroscopy (EIS) measurement of the battery module 1. It is possible to improve accuracy because a magnitude of the AC discharge current can be set to a relatively large value during electrochemical impedance spectroscopy (EIS) measurement of the battery module 1.

The present disclosure has been described in detail through specific exemplary embodiments. The foregoing description is merely illustrative of examples applying the principles of the present disclosure, and other configurations may be further included or substituted with other components within a range not departing from the scope of the present disclosure.

What is claimed is:

1. An apparatus for measuring electrochemical impedance spectroscopy, the apparatus comprising:
an EIS measurement unit connected to each of a plurality of battery cells included in a battery module and configured to perform electrochemical impedance spectroscopy (EIS) measurement on each of the plurality of battery cells through AC discharge of the battery module; and
an AC discharge switching unit connected to both ends of the battery module and configured to form an AC discharge path such that the battery module performs AC discharge through a pulse width modulation (PWM) control of a switching element when the EIS measurement unit performs electrochemical impedance spectroscopy (EIS) measurement and configured to be used as an additional function through a turn-on control of the switching element when the EIS measurement unit does not perform electrochemical impedance spectroscopy (EIS) measurement.

2. The apparatus of claim 1, wherein the AC discharge switching unit is used for heating the battery module when the EIS measurement unit does not perform electrochemical impedance spectroscopy (EIS) measurement.

3. The apparatus of claim 2, wherein the AC discharge switching unit comprises:
a multifunction switching unit electrically connected to the battery module including the plurality of battery cells and configured to comprise the switching element for generating an alternating current;
a switching control unit configured to control the switching element by pulse width modulation (PWM) according to a predetermined frequency when electrochemical impedance spectroscopy (EIS) measurement is performed, and to control the switching element in an on/off manner when electrochemical impedance spectroscopy (EIS) measurement is not performed;
a multipurpose function unit connected between the battery module and the multifunction switching unit and configured to form the AC discharge path when the switching element is controlled by pulse width modulation (PWM), or to function for heating the battery module when the switching element is turned on; and
a sensing resistor unit connected between the battery module including the plurality of battery cells and the multifunction switching unit.

4. The apparatus of claim 3, wherein the EIS measurement unit, the multifunction switching unit, and the switching control unit are included in a battery management system (BMS) for managing a state of the battery module.

5. The apparatus of claim 3, wherein the multipurpose function unit comprises a heater resistor to be mounted on the battery module for heating the battery module.

6. The apparatus of claim 5, wherein one end of the heater resistor is connected to a positive terminal of the battery module and the other end of the heater resistor is connected to the switching element of the multifunction switching unit, and
the multipurpose function unit forms the AC discharge path of the battery module through the heater resistor by allowing the switching control unit to control the switching element of the multifunction switching unit by pulse width modulation (PWM) during electrochemical impedance spectroscopy (EIS) measurement.

7. The apparatus of claim 5, wherein one end of the heater resistor is connected to a positive terminal of the battery module and the other end of the heater resistor is connected to the switching element of the multifunction switching unit, and
the multipurpose function unit uses the heater resistor for heating the battery module by allowing the switching control unit to turn on the switching element of the multifunction switching unit when electrochemical impedance spectroscopy (EIS) measurement is not performed.

8. The apparatus of claim 3, wherein the AC discharge switching unit further comprises a fault diagnosis switch having one end thereof connected between the multipurpose function unit and the multifunction switching unit and the other end connected to a negative terminal of the battery module.

9. The apparatus of claim 3, wherein when the switching control unit controls the switching element of the multifunction switching unit by pulse width modulation (PWM) according to a predetermined AC frequency such that AC discharge is performed in the battery module through the multipurpose function unit,
the EIS measurement unit operates
to receive a value obtained by measuring an AC discharge current formed on the switching element using the sensing resistor unit by the switching control unit,
to measure an AC discharge voltage reacting to each of the plurality of battery cells included in the battery module, and
to calculate an impedance for each of the plurality of battery cells using the measured AC discharge current and the measured discharge voltage.

10. The apparatus of claim 1, wherein EIS measurement protective fuses for protecting each electrochemical impedance spectroscopy (EIS) measurement path are connected between the EIS measurement unit and respective nodes of the plurality of battery cells included in the battery module.

11. A method for measuring electrochemical impedance spectroscopy, the method comprising:
generating an alternating current corresponding to a frequency for electrochemical impedance spectroscopy (EIS) measurement of a battery module by an AC discharge switching unit connected to the battery module including a plurality of battery cells; and
performing electrochemical impedance spectroscopy (EIS) measurement on each of the plurality of battery cells included in the battery module by an EIS measurement unit connected to respective nodes of the plurality of battery cells included in the battery module,
wherein the AC generation step comprises:
controlling, by a switching control unit of the AC discharge switching unit, a switching element of a multifunction switching unit in a pulse width modulation (PWM) manner; and
forming an AC discharge path passing through a multipurpose function unit by repetitive on/off operation of the switching element under a pulse width modulation (PWM) control, such that the battery module performs AC discharge.

12. The method of claim 11, wherein the EIS measurement step comprises:
receiving, by the EIS measurement unit, an AC discharge current measurement value from the switching control unit that measures an AC discharge current formed on the switching element using a sensing resistor unit;
measuring, by the EIS measurement unit, an AC discharge voltage that reacts to each of the plurality of battery cells included in the battery module; and
calculating, by the EIS measurement unit, an impedance for each of the plurality of battery cells using the measured AC discharge current and the measured AC discharge voltage.

13. The method of claim 11, further comprising:
an additional function step of operating the multipurpose function unit as an additional function by turning on the switching element of the multifunction switching unit under control of the switching control unit of the AC discharge switching unit when the EIS measurement unit does not perform electrochemical impedance spectroscopy (EIS) measurement.

14. The method of claim 13, wherein the additional function step uses the multipurpose function unit for heating the battery module.

15. The method of claim 11, further comprising:
diagnosing whether the switching element of the multifunction switching unit is faulty,
wherein the fault diagnosis step uses a fault diagnosis switch having one end connected between the multipurpose function unit and the multifunction switching unit and the other end connected to a negative terminal of the battery module.
